(19) United States
(12) Patent Application Publication
(10) Pub. No.: US 2017/0350007 A1
(43) Pub. Date: Dec. 7, 2017

(54) POST COATING SURFACE TREATMENT FOR METALLIC PART

(71) Applicant: Caterpillar Inc., Peoria, IL (US)

(72) Inventors: Bao Feng, Peoria, IL (US); Steven Charles Taylor, Washington, IL (US)

(21) Appl. No.: 15/171,111

(22) Filed: Jun. 2, 2016

(51) Int. Cl. C23C 16/26; C23C 14/32; C23C 14/06; C23C 14/58; C23C 14/34

(52) U.S. Cl. CPC C23C 16/26; C23C 14/588; C23C 14/34; C23C 14/0635; C23C 14/0658; C23C 14/0641; C23C 14/325

(57) ABSTRACT

A method of surface treating a metallic part includes steps of coating the metallic part with a tribological thin film coating, and tumbling the metallic part after the coating step to remove surface micro-particles. The tumbling step may also remove delaminated areas of the tribological thin film coating. According to some embodiments, the metallic part may be tumbled with an alkaline solution.

### TECHNICAL FIELD

The present disclosure relates generally to a surface treatment for a metallic part, and more particularly to a post coating tumbling process for the metallic part.

### BACKGROUND

Tribological thin films, or coatings, are provided in a variety of machining applications, to create parts having hard and smooth surface finishes. The coating materials and processes for applying the coatings to different parts may vary depending on applications for the parts. For example, different properties may be more desirable than others, depending on the particular application. Further, manufacturing constraints may dictate which materials and treatments are viable. However, it should be appreciated that defects in the resulting coatings may lead to performance issues with the machining application.

U.S. Pat. No. 6,869,334 to Leyendecker et al. discloses a process for producing a hard-material-coated component that includes applying a layer of hard material to a component using a physical vapor deposition (PVD) process. The disclosed process also includes blasting a surface of the hard material layer with an inorganic blasting agent having a sharp-edged grain shape in a blasting device in order to smooth the surface of the component. The Leyendecker disclosure relates to coatings of a relatively great thickness, and also relates to a blasting process that smoothens the coating, likely reducing the material thickness thereof, using a harsh and possibly destructive surface treatment.

As should be appreciated, there is a continuing need to provide improved systems and methods for efficiently providing tribological thin film coatings for parts, such as metallic parts, and identifying defects for the same.

### SUMMARY OF THE INVENTION

In one aspect, a method of surface treating a metallic part includes steps of coating the metallic part with a tribological thin film coating, and tumbling the metallic part after the coating step to remove surface micro-particles. The tumbling step may also remove delaminated areas of the tribological thin film coating.

In another aspect, a metallic part is surface treated by a process including steps of coating the metallic part with a tribological thin film coating, and tumbling the metallic part after the coating step to remove surface micro-particles. After the tumbling step, voids exist where the surface micro-particles have been removed, and a thickness of the tribological thin film coating remains approximately the same before and after the tumbling step.

### BRIEF DESCRIPTION OF THE DRAWINGS

FIG. 1 is a partially sectioned side view of a fuel pump that may include a metallic part coated and treated as disclosed herein, according to one embodiment of the present disclosure;

FIG. 2 is a magnified surface view of a metallic part prior to the surface treatment described herein, according to one aspect of the present disclosure;

FIG. 3 is a magnified surface view of the metallic part of FIG. 2, after the surface treatment described herein, depicting removal of micro-particles, according to another aspect of the present disclosure;

FIG. 4 is a bar graph depicting results of a high frequency reciprocating rig test, illustrating lubricity of a metallic part before and after the surface treatment described herein;

FIG. 5 is a chart depicting coating thicknesses before and after the surface treatment described herein, according to another aspect of the present disclosure;

FIG. 6 is a picture highlighting a poor coating adhesion area of a part;

FIG. 7 is a picture of the same part area highlighted in FIG. 6 after applying the surface treatment disclosed herein for approximately one hour, according to another aspect of the present disclosure; and

FIG. 8 is a picture of the same part area highlighted in FIGS. 6 and 7 after applying the surface treatment disclosed herein for approximately two hours, according to another aspect of the present disclosure.

### DETAILED DESCRIPTION

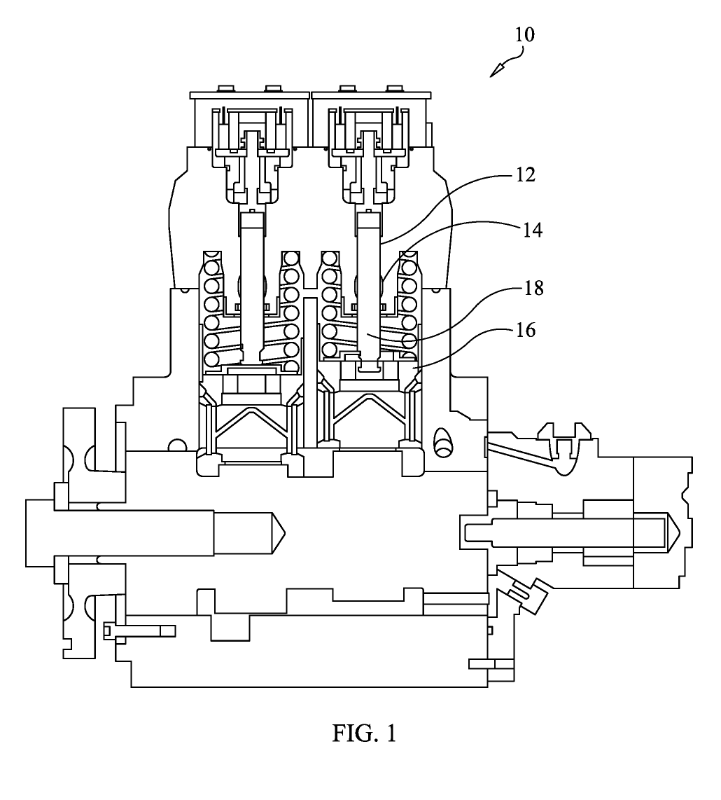

As is shown in FIG. 1, an exemplary fuel pump 10 may include at least one metallic part 12, according to the present disclosure. The metallic part 12 may be a fuel system plunger 14, as shown. The fuel system plunger 14 may be used in the fuel pump 10 or an injector of a fuel system, may be made from or coated in a metallic material, and may be used in a sliding or reciprocating application. For example, the fuel system plunger 14, according to typical operation, may be received within a barrel 16 and, thus, an exterior surface of the fuel system plunger 14 and an interior surface of the barrel 16 may repeatedly contact or engage one another during operation.

Although the teachings presented herein may be applicable to a variety of different parts manufactured from a variety of different materials and used in a variety of different applications, an exemplary embodiment is provided herein for purposes of better illustrating the disclosure. The illustrative embodiment is in no way intended to unduly limit the scope of the application.

According to the present disclosure, the metallic part 12 may be coated with a tribological thin film coating 18, as is known by those skilled in the art. Although some properties exhibited by the tribological thin film coating 18 may emerge as more important than others depending on the particular application, some properties, such as, for example, hardness and ductility may generally be important properties for most parts.

There are a variety of different ways to apply or deposit the tribological thin film coating 18 on the part. For example, processes, including chemical vapor deposition (CVD), physical vapor deposition (PVD), cathode arc processing and sputtering have all been used to deposit thin film coatings made from, for example, titanium carbide (TiC) or titanium nitride (TiN), or superlattice, multilayer, nanostructured, MAX phase, and carbon nitride (a form of diamond-like-carbon (DLC) film coatings). Of course, alternative coatings and processes are also applicable to the present disclosure.

Many DLC films are produced by PVD techniques including cathodic arc, filtered cathodic arc, sputtering, reactive sputtering, and low pressure CVD, and plasma assisted or plasma enhanced CVD processes. The hardness of DLC films typically covers the range from hard to superhard with hardness ranging between 10-80 GPA. Whereas hard coatings such as titanium nitride, titanium aluminum nitride, and multilayer films have been very successful for tooling applications, the DLC films have been very successful where low friction and low wear are needed such as on gears and bearings. Of course alternative embodiments and/or manufacturing constraints may warrant different materials and/or deposition processes.

According to an exemplary embodiment, the tribological thin film coating 18 may be a DLC film coating, such as an amorphous DLC film coating, as is known in the art. According to some embodiments, the DLC film coating may be combined with an additional coating in one cycle, as a duplex coating. For example, chrome nitriding or ion plasma nitriding and DLC may be combined into one cycle as a duplex coating.

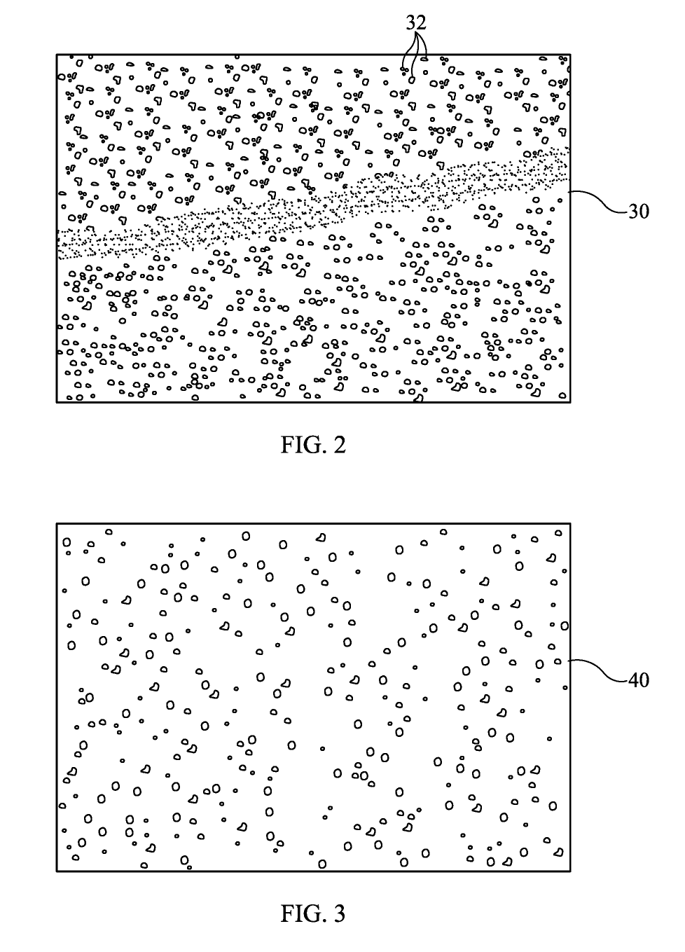

Some tribological thin films for sliding applications have been found to suffer defect induced performance issues. The defects in thin films may include micro-particles attached to the part surface during the deposition process and the voids that exist once those micro-particles with coating on top are removed. Tribological test results show such surface features make thin films more abrasive to the counter surface. For example, see the abrasive surface of a DLC coated flat sample 30 in FIG. 2 having a high number of surface micro-particles 32.

According to the present disclosure, the metallic part 12 may be tumbled after the coating step to remove surface micro-particles 32. Tumbling, a process known in the art, is often used on metallic parts as a surface finish tool to produce an isotropic and super smooth surface morphology. Normally, however, it consists of two steps: first, tumble with a stone and acid mix to expedite material removal; second, tumble with an alkaline solution to neutralize the acid in the first step and also to create a slippery surface condition so the polishing stone only shines and polishes the surface instead of removing noticeable material.

According to the present disclosure, the conventional tumbling process will not be used. That is, the first step in the conventional process will not be used. Instead, the coated metallic part 12 may simply be tumbled with an alkaline solution. The tumbling process removes surface micro-particles 32 and removes delaminated areas of the tribological thin film coating 18. Results are shown at sample 40 in FIG. 3, depicting the DLC coated flat sample of FIG. 2 after the tumbling process disclosed herein, i.e., after the coated metallic part 12 has been tumbled with the alkaline solution.

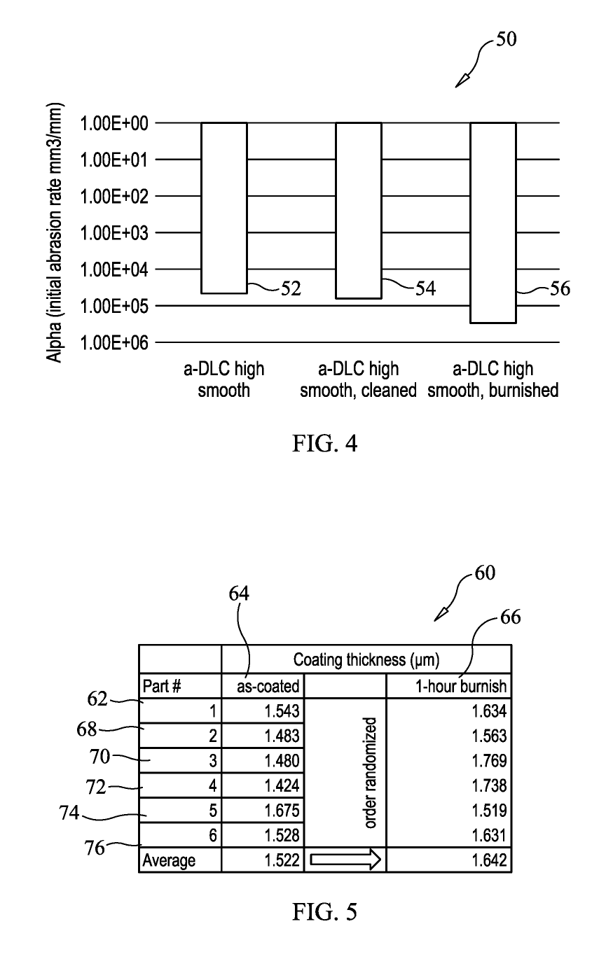

A high frequency reciprocating rig (HFRR) may be used for testing and measuring lubricity. Turning now to FIG. 4, HFRR test results show, in a chart 50, the abrasiveness of the same coating dropped by an order of magnitude after burnishing, or tumbling (as described herein). The bar 52 on the left side shows an as-is a-DLC coated flat sample. The middle bar 54 represents the sample after it has been cleaned. The bar 56 on the right side shows the sample after it's been tumbled, or burnished, with an alkaline solution.

FIG. 5 is a chart 60, depicting coating thickness test results confirming that the burnishing, or tumbling, process does not reduce the thickness of the coatings, or thin films. According to the test, six fuel system plungers, coated with Duplex coatings, are burnished for approximately one hour. Coating thicknesses before and after burnishing may be measured, for example, by ball cratering testing (the accuracy is in the order of +/−0.2 μm). As shown, there is no noticeable coating thickness change caused by burnishing.

That is, as shown in row 1 (62), column 64 represents the coating thickness of the part, as coated, while column 66 represents the coating thickness approximately one hour after burnishing. In particular, row 1 (62) shows that part 1 was 1.543 μm thick before burnishing and 1.634 μm thick after burnishing. Row 2 (68) shows that part 2 was 1.483 μm thick before burnishing and 1.563 μm thick after burnishing. Row 3 (70) shows that part 3 was 1.480 μm thick before burnishing and 1.769 μm thick after burnishing. Row 4 (72) shows that part 4 was 1.424 μm thick before burnishing and 1.738 after burnishing. Row 5 (74) shows that part 5 was 1.675 μm thick before burnishing and 1.519 μm thick after burnishing. Row 6 (76) shows that part 6 was 1.528 μm thick before burnishing and 1.631 μm thick after burnishing.

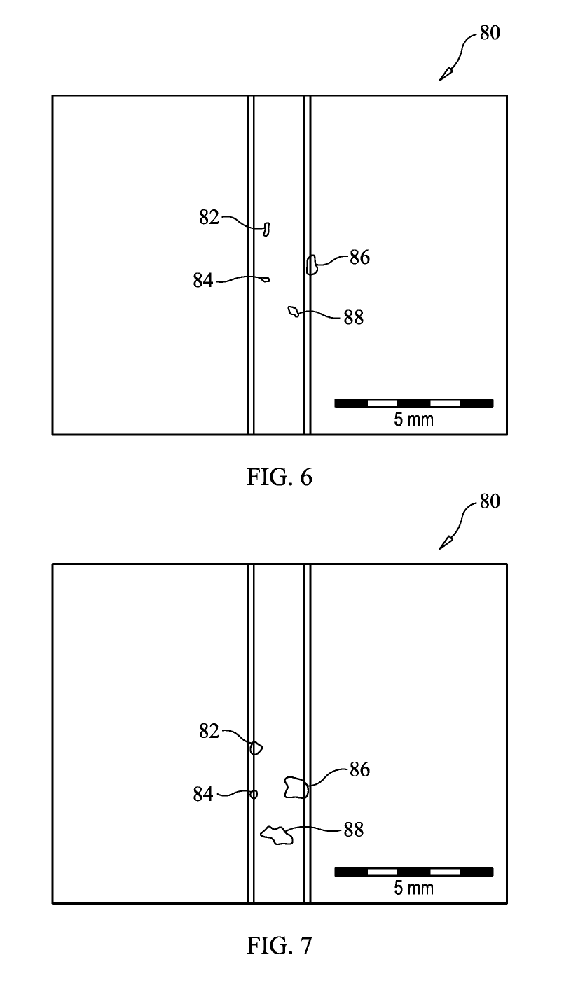

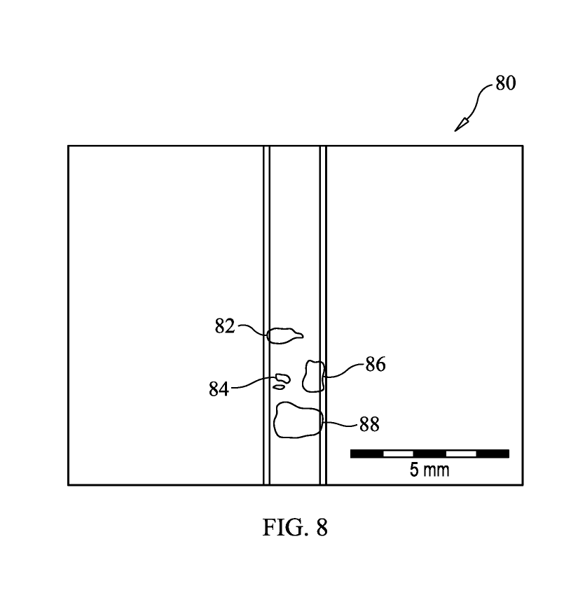

FIGS. 6, 7 and 8 show pictures at different stages of the burnishing, or tumbling, process, illustrating how the burnishing process effectively removes coating with poor adhesion both at or around areas with initial coating delamination and at or around areas that don't initially have coating delamination. For example, FIG. 6 shows an as-coated area 80 with poor coating adhesion, such as one that might be ignored during a quality control (QC) check. In particular, areas of delamination are shown at 82, 84, 86, and 88. FIG. 7 shows the same area after burnishing for one hour, and FIG. 8 shows the same area after burnishing for two hours. As such, these areas of delamination 82, 84, 86, 88 may be more clearly identified during the QC process after undergoing the tumbling process disclosed herein.

### INDUSTRIAL APPLICABILITY

The present disclosure is applicable to parts having tribological thin film coatings. More particularly, the present disclosure is applicable to post coating surface treatments for parts, such as metallic parts, for improving the quality of the coating and/or identifying coating defects. Yet further, the present disclosure may find particular applicability in parts used in sliding applications.

Referring generally to FIGS. 1-8 presented above, an exemplary metallic part 12 may include a fuel system plunger 14 coated with a tribological thin film coating 18. According to some embodiments, the coating 18 may be a DLC coating and/or may be a duplex coating. Tribological thin films for sliding applications have been found to suffer defect induced performance issues. The defects in thin films, specifically, include the micro-particles attached to the part surface during the deposition process and the voids that exist once those micro-particles with coating on top are removed. For example, see the abrasive surface of a DLC coated flat sample 30 in FIG. 2 having a high number of surface micro-particles 32. Tribological test results show such surface features make thin films more abrasive to the counter surface.

In thin film production, coating adhesion is typically checked by sampling small quantities of parts. Large sized coating defects such as water marks or finger prints covered by coating are easily missed in visual inspection. For both scenarios, a commonly used enhancement is a post process ultrasonic wash. According to this process, a coating with poor adhesion or large defects may have resulting delaminate portions and become easier to be identified. However, parts with poor coating adhesion are still often found at the customer end.

According to the present disclosure, the metallic part 12 may be tumbled with an alkaline solution after the coating step to remove surface micro-particles 32. After the tumbling step, voids exist where the surface micro-particles have been removed, and a thickness of the tribological thin film coating remains approximately the same before and after the tumbling. The distinction in color between the silver metallic part and the dark DLC coating help to more easily identify defects or issues with the coating, e.g., the delaminate portions. According to some quality control standards, parts with coating delamination during production are required to be scrapped. The process disclosed herein makes areas of delamination more visible, as described above, such that the parts may be identified and removed for scrap more easily.

Although other methods may be used, tumbling requires no operator attendance and, as such, may be more productive compared with, for example, a bead blast process where an operator or a robot needs to aim a nozzle at the coated parts one by one. In addition, tumbling provides thorough micro-particle removal compared with lapping or polishing, which leave debris in the voids where the micro-particles initially reside. Further, tumbling is more effective at loose coating removal as compared to ultrasonic wash.

It should be understood that the above description is intended for illustrative purposes only, and is not intended to limit the scope of the present disclosure in any way. Thus, those skilled in the art will appreciate that other aspects of the disclosure can be obtained from a study of the drawings, the disclosure and the appended claims.

What is claimed is:

1. A method of surface treating a metallic part, the method including steps of:
coating the metallic part with a tribological thin film coating; and
tumbling the metallic part after the coating step to remove surface micro-particles.

2. The method of claim 1, wherein the tumbling step includes tumbling the metallic part with an alkaline solution.

3. The method of claim 1, wherein the tumbling step includes removing delaminated areas of the tribological thin film coating.

4. The method of claim 1, wherein the coating step includes coating the metallic part with a diamond-like carbon coating.

5. The method of claim 4, wherein the coating step includes coating the metallic part with a duplex coating.

6. The method of claim 2, wherein the tumbling step lasts less than two hours.

7. The method of claim 6, wherein the tumbling step lasts approximately one hour.

8. The method of claim 2, wherein the tumbling step includes burnishing the metallic part.

9. The method of claim 2, wherein the coating step includes coating a fuel system plunger.

10. The method of claim 2, wherein the coating step includes coating the metallic part to a coating thickness between about 1 micron and about 2 microns.

11. The method of claim 10, wherein, after the tumbling step, the coating thickness remains between about 1 micron and about 2 microns.

12. A metallic part surface treated by a process including steps of:
coating the metallic part with a tribological thin film coating; and
tumbling the metallic part after the coating step to remove surface micro-particles;
wherein, after the tumbling step, voids exist where the surface micro-particles have been removed, and a thickness of the tribological thin film coating remains approximately the same before and after the tumbling step.

13. The metallic part of claim 12, wherein the tumbling step includes tumbling the metallic part with an alkaline solution.

14. The metallic part of claim 13, wherein, after the tumbling step, voids exist where delaminated areas of the tribological thin film coating have been removed.

15. The metallic part of claim 12, wherein the coating step includes coating the metallic part with a diamond-like carbon coating.

16. The metallic part of claim 15, wherein the coating step includes coating the metallic part with a duplex coating.

17. The metallic part of claim 13, wherein the tumbling step lasts less than two hours.

18. The metallic part of claim 17, wherein the tumbling step lasts approximately one hour.

19. The metallic part of claim 12, wherein the metallic part is a fuel system plunger.

20. The metallic part of claim 12, wherein the thickness of the tribological thin film coating remains between about 1 micron and 2 microns before and after the tumbling step.
